(19) United States
(12) Patent Application Publication
(10) Pub. No.: US 2007/0015364 A1
(43) Pub. Date: Jan. 18, 2007

(54) METHOD FOR AVOIDING EXPOSURE OF VOID CAUSED BY DIELECTRIC GAP-FILLING, AND FABRICATING PROCESS AND STRUCTURE OF DIELECTRIC FILM

(76) Inventor: Sheng-Cheng Hsieh, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/160,926

(22) Filed: Jul. 15, 2005

(51) Int. Cl. C23F 1/00; H01L 21/461; H01L 21/302

(52) U.S. Cl. 438/692; 216/41; 257/758

(57) ABSTRACT

A method for avoiding exposure of a void caused by dielectric gap-filling is described. An etching-resistant layer is formed on only a portion of the dielectric layer over the gap covering at least the dielectric layer over the void, so that the void is not exposed in a subsequent etching process.

### BACKGROUND OF THE INVENTION

1. Field of the Invention

The present invention relates to a semiconductor process and a film structure. More particularly, the present invention relates to a method for avoiding exposure of a void caused by dielectric gap-filling, and a fabricating process and a structure of a dielectric film.

2. Description of the Related Art

In semiconductor manufacture, dielectric gap-filling process forming a dielectric layer to fill a gap on a substrate is frequently applied to, for example, inter-metal dielectric (IMD) process, inter-poly dielectric (IPD) process or shallow trench isolation (STI) process.

However, when the gap-filling effect of the dielectric material is poor in the dielectric gap-filling process, the dielectric material deposited on different top edges of the gap easily connect together before the gap is filled up, so that a closed void is formed in the dielectric layer. The void will possibly be exposed in a subsequent etching process to cause contamination or filling of conductive material into the void.

### SUMMARY OF THE INVENTION

Accordingly, this invention provides a method for avoiding exposure of a void caused by dielectric gap-filling to prevent the problems caused by exposure of the void.

Another object of this invention is to provide a fabricating process of a dielectric film that is capable of preventing a void in a dielectric layer filled in a gap from being exposed in a subsequent etching process.

Still another object of this invention is to provide a structure of a dielectric film that is formed with the fabricating process of a dielectric film of this invention.

In the method for avoiding exposure of a void caused by dielectric gap-filling of this invention, an etching-resistant layer is formed on only a portion of the dielectric layer over the gap, covering at least the dielectric layer over the void to protect the void from being exposed in a subsequent etching process.

In an embodiment, the etching-resistant layer may be formed on only the portion of the dielectric layer by forming a layer of etching-resistant material all over the dielectric layer and then removing the etching-resistant material not on the portion of the dielectric layer.

The etching-resistant material not on the portion of the dielectric layer may be removed generally through chemical mechanical polishing (CMP) or a lithography-etching process. The etching-resistant material may be formed through chemical vapor deposition (CVD) or a liquid coating process. The CVD process may be a low-pressure CVD (LPCVD) process, a plasma enhanced CVD (PECVD) process, an atmospheric pressure CVD (APCVD) process or a high-density plasma CVD (HDP-CVD) process.

In addition, the liquid coating process may be a spin-on coating process. Moreover, when the etching-resistant material is formed through liquid coating, the etching-resistant material not on the portion of the dielectric layer may be removed through CMP, etching-back or a lithography-etching process.

The fabricating process of a dielectric film of this invention is described as follows. A first dielectric layer is formed on a substrate with a gap thereon, filling in the gap and forming a closed void therein. An etching-resistant layer is formed on only a portion of the first dielectric layer over the gap, covering at least the first dielectric layer over the void. A second dielectric layer is then formed on the first dielectric layer and the etching-resistant layer.

In the method for forming a dielectric film of this invention, the first dielectric layer and the second dielectric layer may include the same material. Other features about the etching-resistant layer are similar to those mentioned above.

In addition, the first dielectric layer may include an inter-metal dielectric (IMD) layer or an STI layer. Moreover, when the first dielectric layer includes silicon oxide, the etching-resistant layer preferably includes SiON, SiN or BN.

The dielectric film structure of this invention includes a first dielectric layer, an etching-resistant layer and a second dielectric layer. The first dielectric layer is disposed on a substrate with a gap thereon, filling in the gap and forming a closed void therein. The etching-resistant layer is disposed on only a portion of the first dielectric layer over the gap, covering at least the first dielectric layer over the void. The second dielectric layer is disposed on the first dielectric layer and the etching-resistant layer.

In the dielectric film structure of this invention, the etching-resistant layer may include a CVD material, i.e., a material formed through CVD, or a spin-on material. The etching-resistant layer including a CVD material is possibly substantially conformal to the portion of the first dielectric layer, while the etching-resistant layer including a spin-on material can have a planar upper surface.

Since an etching-resistant layer is formed, after a dielectric gap-filling process, on a portion of the dielectric layer over the gap covering the first dielectric layer over the void, the void is not exposed in a subsequent etching process to cause problems.

It is to be understood that both the foregoing general description and the following detailed description are exemplary, and are intended to provide further explanation of the invention as claimed.

### BRIEF DESCRIPTION OF THE DRAWINGS

FIGS. 1-2 illustrate a fabricating process of a dielectric film according to a first embodiment of this invention in a cross-sectional view.

FIG. 3 illustrates another method for forming the etching-resistant layer in the first embodiment of this invention.

FIGS. 4-5 illustrate a fabricating process of a dielectric film according to a 2nd embodiment of this invention in a cross-sectional view.

FIG. 6 illustrates another method for forming the etching-resistant layer in the second embodiment of this invention.

### DESCRIPTION OF THE PREFERRED EMBODIMENTS

### First Embodiment

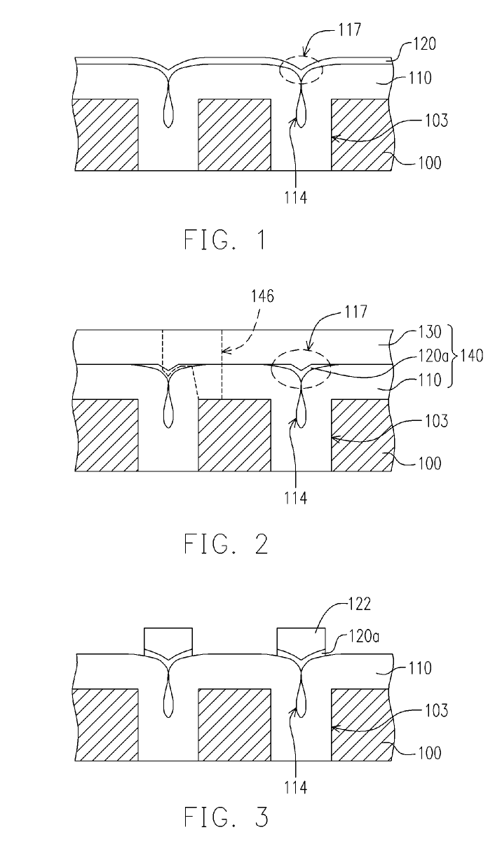

FIGS. 1-2 illustrate a fabricating process of a dielectric film according to the first embodiment of this invention in a cross-sectional view.

Referring to FIG. 1, a substrate 100 formed with gaps 103 thereon is provided, which may be a substrate formed with doped polysilicon lines or metal lines thereon. In such a case, the gaps 103 are defined between the lines, while the dielectric film to be formed serves as an IPD film or an IMD film. The substrate 100 may alternatively be one having been subject to a part of an STI process to have shallow trenches formed thereon, while a portion of the dielectric film to be formed serves as an STI layer.

Next, a lower dielectric layer 110 that may include silicon oxide, for example, is deposited on the substrate 100. The gap-filling effect of the lower dielectric layer 110 is poor so that a closed void 114 is formed in the lower dielectric layer 110 in the gap 103. Meanwhile, a recess 117 is present at the lower dielectric layer 110 over one gap 103. Then, a layer of etching-resistant material 120 is deposited over the substrate 100 through CVD, wherein the CVD may be LPCVD, PECVD, APCVD or HDP-CVD, and the etching-resistant material 120 is substantially conformal with 110.

In addition, when the lower dielectric layer 110 serves as an IPD or IMD layer and includes silicon oxide, the etching-resistant material 120 may be SiON, SiN or BN, etc. When the lower dielectric layer 110 serves as an STI layer and includes silicon oxide, the etching-resistant material 120 may be SiON or SiN, etc. Any one of SiON, SiN and BN has an etching selectivity much lower than that of silicon oxide, so that the lower dielectric layer 110 over the void 114 can be effectively protected from being etched away to expose the void 114 in a subsequent etching process, such as, a contact-hole etching process.

Referring to FIG. 2, the etching-resistant material 120 outside the recess 117 is removed through, for example, CMP. The CMP process is performed at least until the surface of the lower dielectric layer 110 is exposed, so that an etching-resistant layer 120a is formed in a recess 117 of the lower dielectric layer 110 covering the lower dielectric layer 110 over a void 114. When the deposition thickness of the etching-resistant material 120 is insufficient to fill the recess 117 as shown in FIG. 2, the etching-resistant layer 120a is slightly conformal with the lower dielectric layer 110 under it. When the deposition thickness is sufficient to fill the recess 117 (not shown), the etching-resistant layer 120a can have a planar upper surface.

Thereafter, an upper dielectric layer 130 is formed on the lower dielectric layer 110 and the etching-resistant layer 120a, wherein the material of the upper dielectric layer 130 can be the same as that of 110, such as, silicon oxide. Thus, a dielectric film 140 according to the first embodiment of this invention is finished, including the lower dielectric layer 110, the etching-resistant layer 120a and the upper dielectric layer 130 arranged as mentioned above. When the lower dielectric layer 110 is an IPD or IMD layer, the upper dielectric layer 130 is also an IPD or IMD layer. However, when the lower dielectric layer 110 is an STI layer, the upper dielectric layer 130 is, for example, the first IPD layer of the whole semiconductor process that is usually not formed directly after the etching-resistant layer 120a but after the first poly-Si layer of the whole semiconductor process, e.g., a poly-Si gate layer, is formed.

In addition, the etching-resistant layer 120a can alternatively be formed through a lithography-etching process, as shown in FIG. 3. Photoresist patterns 122 are formed on the etching-resistant material 120 over the gaps 103, and then the etching-resistant material 120 is etched using the photoresist patterns 122 as a mask. The etching-resistant layer 120a such formed is substantially conformal with the lower dielectric layer 110 under it. In addition, the upper dielectric layer 130 is formed after the photoresist patterns 122 are removed and the substrate 100 is cleaned.

### Second Embodiment

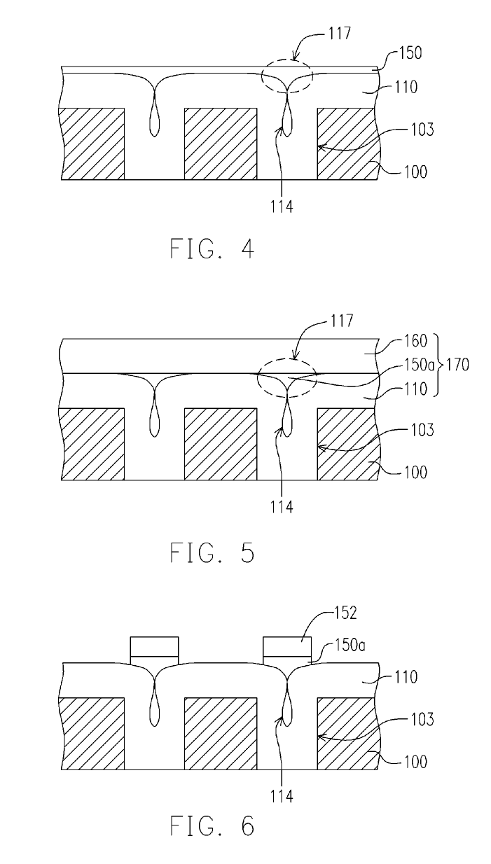

FIGS. 4-5 illustrate a fabricating process of a dielectric film according to the second embodiment of this invention in a cross-sectional view.

Referring to FIG. 4, a substrate 100 formed with gaps 103 thereon is provided, and then a lower dielectric layer 110 is deposited on the substrate 100. The gap-filling effect of the lower dielectric layer 110 is poor so that a closed void 114 is formed in the lower dielectric layer 110 in a gap 103. Meanwhile, a recess 117 is present at the lower dielectric layer 110 over one gap 103. The substrate 100 and the lower dielectric layer 110 may be the same as those mentioned above.

Thereafter, a liquid coating method like spin-on coating is used to form a layer of etching-resistant material 150, which should have a sufficiently low etching selectivity relative to that of the lower dielectric layer 110, so as to effectively prevent the void 114 in the lower dielectric layer 110 from being exposed. When the lower dielectric layer 110 includes silicon oxide, the etching-resistant material 150 can be spin-on glass (SOG) or organic spin-on material, which can have relatively low etching selectivity as compared with SiO under certain conditions. Since the etching-resistant material 150 is formed through liquid coating, the upper surface thereof is planar.

Referring to FIG. 5, the etching-resistant material 150 outside the recess 117 of the lower dielectric layer 110 is removed through, for example, CMP or etching-back. The CMP or etching-back process is performed at least until the surface of the lower dielectric layer 110 is exposed, so that an etching-resistant layer 150a is left in the recess 117 covering the lower dielectric layer 110 over the void 114. The etching-resistant layer 150a still has a planar upper surface.

Thereafter, an upper dielectric layer 160 is formed on the lower dielectric layer 110 and the etching-resistant layer 150a, wherein the material of the upper dielectric layer 160 can be the same as that of 110, such as, silicon oxide. Thus, a dielectric film 170 according to the second embodiment of this invention is formed, including the lower dielectric layer 110, the etching-resistant layer 150a and upper dielectric layer 160 arranged as mentioned above.

In addition, the etching-resistant layer 150a can alternatively be formed through a lithography-etching process, as shown in FIG. 6. Photoresist patterns 152 are formed on the etching-resistant material 150 over the gaps 103, and then the etching-resistant material 150 is etched using the photoresist patterns 152 as a mask. The etching-resistant layer 150a such formed still has a planar upper surface. In addition, the upper dielectric layer 160 is formed after the photoresist patterns 152 are removed and the substrate 100 is cleaned.

As mentioned above, the first and second embodiments of this invention respectively utilize CVD and liquid coating to form an etching-resistant layer covering the dielectric layer over the void, so that the void will not be exposed in a subsequent etching process to cause contamination or filling of conductive material. Taking the structure of FIG. 2 as an example, when misalignment occurs in a subsequent contact-hole process so that the a part of the hole 146 is over the void 114, the etching-resistant layer 120a can effectively prevent the lower dielectric layer 110 over the void 114 from being removed to expose the void 114.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims and their equivalents.

What is claimed is:

1. A method for avoiding exposure of a void caused by dielectric gap-filling, comprising:
forming an etching-resistant layer on only a portion of the dielectric layer over the gap, the etching-resistant layer covering at least the dielectric layer over the void.

2. The method of claim 1, wherein the step of forming an etching-resistant layer on only the portion of the dielectric layer comprises:
forming a layer of etching-resistant material all over the dielectric layer; and
removing the etching-resistant material not on the portion of the dielectric layer.

3. The method of claim 2, wherein the step of removing the etching-resistant material not on the portion of the dielectric layer comprises a CMP process or a lithography-etching process.

4. The method of claim 2, wherein the step of forming a layer of etching-resistant material comprises a CVD process or a liquid coating process.

5. The method of claim 4, wherein the CVD process comprises an LPCVD process, a PECVD process, an APCVD process or an HDP-CVD process.

6. The method of claim 4, wherein the liquid coating process comprises spin-on coating.

7. The method of claim 4, wherein
the step of forming a layer of etching-resistant material comprises a liquid coating process; and
the step of removing the etching-resistant material not on the portion of the dielectric layer comprises a CMP process, an etching-back process or a lithography-etching process.

8. A fabricating process of a dielectric film that is applied to a substrate formed with a gap thereon, comprising:
forming a first dielectric layer on the substrate, filling in the gap and forming a closed void therein;
forming an etching-resistant layer on only a portion of the first dielectric layer over the gap, the etching-resistant layer covering at least the first dielectric layer over the void; and
forming a second dielectric layer on the first dielectric layer and the etching-resistant layer.

9. The method of claim 8, wherein the first dielectric layer and the second dielectric layer comprise the same material.

10. The method of claim 8, wherein the step of forming an etching-resistant layer on only the portion of the first dielectric layer comprises:
forming a layer of etching-resistant material all over the first dielectric layer; and
removing the etching-resistant material not on the portion of the first dielectric layer.

11. The method of claim 10, wherein the step of removing the etching-resistant material not on the portion of the first dielectric layer comprises a CMP process or a lithography-etching process.

12. The method of claim 10, wherein the step of forming a layer of etching-resistant material comprises a CVD process or a liquid coating process.

13. The method of claim 12, wherein the CVD process comprises an LPCVD process, a PECVD process, an APCVD process or an HDP-CVD process.

14. The method of claim 12, wherein the liquid coating process comprises spin-on coating.

15. The method of claim 12, wherein
the step of forming a layer of etching-resistant material comprises a liquid coating process; and
the step of removing the etching-resistant material not on the portion of the dielectric layer comprises a CMP process, an etching-back process or a lithography-etching process.

16. The method of claim 8, wherein the first dielectric layer comprises an inter-metal dielectric (IMD) layer or a shallow trench isolation (STI) layer.

17. The method of claim 8, wherein the first dielectric layer comprises silicon oxide, and the etching-resistant layer comprises SiON, SiN or BN.

18. A dielectric film structure, comprising:
a first dielectric layer on a substrate with a gap thereon, filling in the gap and forming a closed void therein;
an etching-resistant layer on only a portion of the first dielectric layer over the gap, covering at least the first dielectric layer over the void; and
a second dielectric layer on the first dielectric layer and the etching-resistant layer.

19. A dielectric film structure of claim 18, wherein the etching-resistant layer comprises a CVD material or a spin-on material.

20. A dielectric film structure of claim 19, wherein the etching-resistant layer comprising a CVD material is substantially conformal with the portion of the first dielectric layer, and the etching-resistant layer comprising a spin-on material has a planar upper surface.
